(19) United States
(12) Patent Application Publication
(10) Pub. No.: US 2025/0359074 A1
(43) Pub. Date: Nov. 20, 2025

(54) MEMORY DEVICES AND METHODS FOR FORMING THE SAME

(71) Applicant: Taiwan Semiconductor Manufacturing Company, Ltd., Hsinchu (TW)

(72) Inventors: Ku-Feng Lin, Hsinchu City (TW); Ji-Kuan Lee, Hsinchu City (TW); Wen-Chun You, Hsinchu City (TW); Perng-Fei Yuh, Hsinchu City (TW); Yi-Chun Shih, Hsinchu City (TW); Yih Wang, Hsinchu City (TW)

(73) Assignee: Taiwan Semiconductor Manufacturing Company, Ltd., Hsinchu (TW)

(21) Appl. No.: 19/282,603

(22) Filed: Jul. 28, 2025

Related U.S. Application Data
(63) Continuation of application No. 18/604,636, filed on Mar. 14, 2024.
(60) Provisional application No. 63/595,618, filed on Nov. 2, 2023.

(51) Int. Cl. H10B 63/00; H10B 53/30

(52) U.S. Cl. CPC H10B 63/80; H10B 53/30

(57) ABSTRACT

A memory device includes a memory array comprising a plurality of memory cells arranged over a plurality of rows, the rows including a plurality of word lines, respectively, a first group of the memory cells coupled to an even-numbered one of the word lines and a second group of the memory cells coupled to an odd-numbered one of the word lines. The even-numbered word line is disposed in a first one of a plurality of metallization layers formed vertically above a substrate, wherein the even-numbered word line extends along a first lateral direction and includes a first stitch portion extending in a second lateral direction perpendicular to the first lateral direction. The odd-numbered word line is disposed in a second one of the plurality of metallization layers, wherein the odd-numbered word line extends along the first lateral direction and includes a second stitch portion extending in the second lateral direction.

### CROSS-REFERENCE TO RELATED APPLICATION

This application is a continuation of U.S. patent application Ser. No. 18/604,636, filed Mar. 14, 2024, which claims priority to and the benefit of U.S. Provisional Application No. 63/595,618, filed Nov. 2, 2023, each of which is incorporated herein by reference in its entirety for all purposes.

### BACKGROUND

The semiconductor integrated circuit (IC) industry has experienced exponential growth. As ICs continue to scale down, more and more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory device including a memory array with a plural number of memory cells, in accordance with some embodiments.

FIG. 2 illustrates an example schematic diagram of the memory cells of FIG. 1, in accordance with some embodiments.

FIG. 3 illustrates an example schematic diagram of a portion of the memory array of FIG. 1, in accordance with some embodiments.

FIG. 4 illustrates an example layout that is configured to form a portion of the memory array of FIG. 1, in accordance with some embodiments.

FIG. 5 illustrates another example layout that is configured to form a portion of the memory array of FIG. 1, in accordance with some embodiments.

FIG. 6 illustrates a first example schematic diagram of a portion of the memory array of FIG. 1, in accordance with some embodiments.

FIG. 7 illustrates an example layout that is configured to form a number of metal tracks illustrated in FIG. 6, in accordance with some embodiments.

FIG. 8 illustrates a cross-sectional view of a semiconductor structure formed based on at least the layout of FIG. 7, in accordance with some embodiments.

FIG. 9 illustrates a second example schematic diagram of a portion of the memory array of FIG. 1, in accordance with some embodiments.

FIG. 10 illustrates an example layout that is configured to form a number of metal tracks illustrated in FIG. 9, in accordance with some embodiments.

FIG. 11 illustrates a cross-sectional view of a semiconductor structure formed based on at least the layout of FIG. 10, in accordance with some embodiments.

FIG. 12 illustrates a cross-sectional view of a semiconductor structure formed based on at least the layout of FIG. 4, in accordance with some embodiments.

FIG. 13 illustrates a cross-sectional view of a semiconductor structure formed based on at least the layout of FIG. 4, in accordance with some embodiments.

FIG. 14 illustrates an example flow chart of a method for fabricating a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Highly integrated semiconductor circuits generally include on-board data storage. Such data storage may take the form of volatile or non-volatile memory cells, for example, in which one or more arrays of capacitive or resistive storage memory cells are provided. In the example of capacitive storage memory cells, a one transistor-one capacitor (1T1C) memory cell is employed, each memory cell having an access transistor and a capacitor; and in the example of resistive storage memory cells, a one transistor-one resistor (1T1R) memory cell is employed, each memory cell having an access transistor and a resistor. In either of the 1T1C or 1T1R implementation, the access transistor having a first source/drain terminal connected to one of the terminals of the capacitor or resistor, and a second source/drain terminal connected to a source or select line (SL). Data stored in such memory cells is typically stored on the capacitor or resistor (sometimes referred to as a storge element). The data is typically accessed by outputting the data to a sense amplifier through a bit line (BL), that is connected to the other terminal of the capacitor or resistor. The data is output when the access transistor is activated, typically by a word line (WL) connected to the gate or control terminal of the access transistor.

Such access lines (WLs, SLs, BLs, etc.) are typically formed as metal tracks across one or more metallization layers disposed over the major (e.g., frontside) surface of a substate. Further, to enable a large array of memory cells implementing a memory device, respective storge elements of the memory cells are formed in one of the metallization layers or between adjacent ones of the metallization layers. With the increasingly advanced trend of technology nodes, dimensions and pitches of these metal tracks shrink accordingly, which causes the access lines to present an increasing resistance. In this regard, some of the access lines (e.g., WLs) are pushed to a metallization layer higher than where the storage elements are formed. As such, some of the storage elements may be enlisted or repurposed as via structures to electrically couple the WLs to the underlying gate terminals of the access transistors. These repurposed storage elements generally present a higher resistance and/or a higher defect rate, when compared to other via structures that are formed of pure metal materials. Accordingly, some of the memory cells may not function as originally designed. Thus, the existing memory devices have not been entirely satisfactory in certain aspects.

The present disclosure provides various embodiments of a memory device including a memory array with a plural number of memory cells, each of which may include at least one switch (e.g., implemented as a transistor) and one storage element (e.g., implemented as a capacitor or resistor). In some embodiments, the memory cells may be non-volatile memory cells. However, it should be understood that the memory cells may be volatile memory cells in some other embodiments, while remaining within the scope of the present disclosure. Different from the existing memory devices, the currently disclosed memory device has its SLs formed in the bottommost metallization layer. Such “relocation” of the SLs allows the WLs to be formed across two adjacent metallization layers that are each vertically below where storage elements are formed. Specifically, the even-numbered WLs are formed in a first metallization layer, and the odd-numbered WLs are formed in a second metallization layer, in which any of the first metallization layer or the second metallization layer is vertically lower than the storage elements. As such, each of the WLs can be electrically coupled to the underlying transistors without the use of the storage elements that may each be implemented as a metal-insulator-metal (MIM) structure. Further, to enable the electrical connection between the WLs and the transistors, each of the WLs may include one or more stitch portions. The term “stitch portion,” as used herein, refers to a portion of a structure protruding from a longitudinal portion of the structure and extending in a direction perpendicular to a direction of the longitudinal portion. Such a stitch portion may sometimes be referred to as an extending or protruding portion. For example, the stitch portions of the even-numbered WLs and the stitch portions of the odd-numbered WLs may extend toward opposite ways. With the even-numbered and odd-numbered WLs disposed in respectively different metallization layers, a density of the memory cells can thus be significantly increased, e.g., by two times. Stated another way, even with the shrunken pitch among laterally adjacent WLs, the density of memory cells of the disclosed memory device can still be improved.

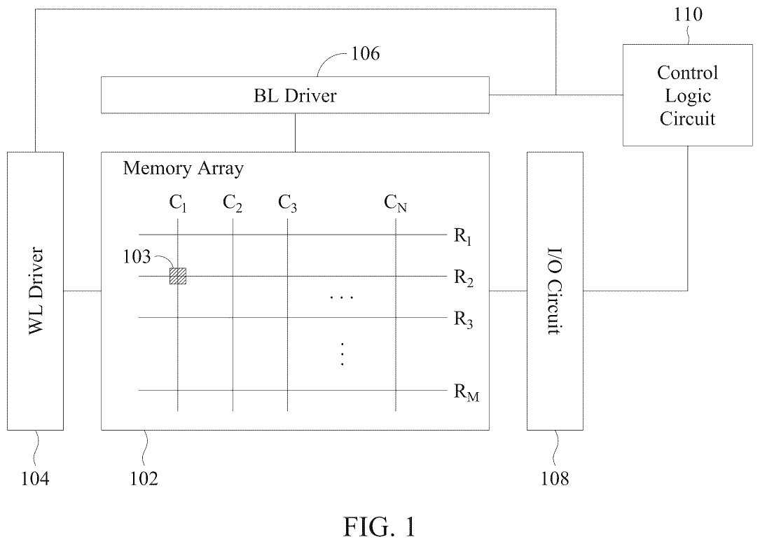

FIG. 1 illustrates a block diagram of a memory device 100, in accordance with various embodiments. As shown, the memory device 100 includes a memory array 102, a WL driver circuit 104, a BL driver circuit 106, an input/output (I/O) circuit 108, and a control logic circuit 110. Despite not being shown in FIG. 1, the components of the memory device 100 may be operatively coupled to each other and to the control logic circuit 112. Although, in the illustrated embodiment of FIG. 1, each component is shown as a separate block for the purpose of clear illustration, in some other embodiments, some or all of the components shown in FIG. 1 may be integrated together. For example, the memory array 102 may include an embedded I/O circuit 108.

The memory array 102 is a hardware component that stores data. In one aspect, the memory array 102 is embodied as a semiconductor memory device. The memory array 102 includes a plurality of memory cells/bits (or otherwise storage units) 103. The memory array 102 includes a number of rows R₁, R₂, R₃ . . . RM, each extending in a first direction and a number of columns C₁, C₂, C₃ . . . CN, each extending in a second direction. Each of the rows/columns may include one or more conductive structures. For example, each column may include at least one bit line (BL) and at least one source or select line (SL), and each row may include at least one word line (WL). In some embodiments, each memory cell 103 is arranged in the intersection of a corresponding row and a corresponding column, and can be operated according to a voltage or current signal conducted through the BL/SL disposed in that column and the WL disposed in that row.

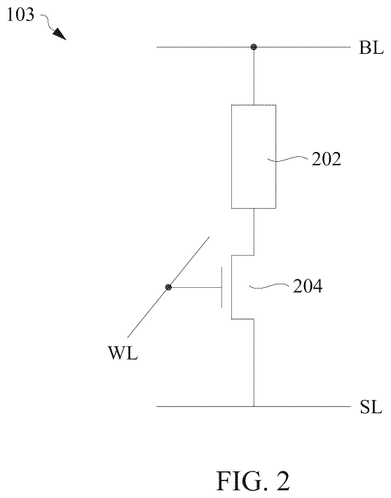

In accordance with various embodiments of the present disclosure, each memory cell 103 is implemented as including a storage element and an access transistor, in which the storage element are coupled to each other in series. The storage element may be a resistor or a capacitor. The configuration of the serially coupled resistor and access transistor is sometimes referred to as 1T1R, and the configuration of the serially coupled capacitor and access transistor is sometimes referred to as 1T1C. The access transistor can be coupled to (e.g., gated by) a corresponding WL. The access transistor can be turned on/off to enable/disable an access (e.g., program, read) to the corresponding memory cell. For example, upon being selected, the access transistor of the selected memory cell is turned on to generate a program or read path conducting through its resistor/capacitor and itself. Detailed descriptions on the 1T1R and 1T1C configurations will be discussed below with respect to FIG. 2.

The WL driver circuit 104 is a hardware component that can receive a row address of the memory array 102 and assert a WL associated with that row address. The BL driver circuit 106 is a hardware component that can receive a column address of the memory array 102 and assert a BL associated with that column address. The I/O circuit 108 is a hardware component that can access (e.g., read, program) each of the memory cells 103 asserted through the WL driver circuit 104 and BL driver circuit 106. The control logic circuit 110 is a hardware component that can control the coupled components (e.g., 102 through 108).

FIG. 2 illustrates an example configuration of the memory cell 103 (FIG. 1), in accordance with various embodiments. As shown, the memory cell 103 includes a storage element 202 and an access transistor 204 coupled to each other in series. In some embodiments, the storge element 202 can include a resistor (e.g., the 1T1R configuration) or a capacitor (e.g., the 1T1C configuration). It, however, should be understood that any of various other memory cell configurations that include at least one access transistor may be used by the memory cell 103 such as, for example, a many-transistor-one-resistor (manyT1R) configuration, a many-transistor-one-capacitor (manyT1C) configuration, etc., while remaining within the scope of the present disclosure.

In the example of the 1T1R configuration, the storage element 202 may be formed between two adjacent ones of a plural number of metallization layers that are disposed vertically above the major surface of a substrate, while the access transistor 204 may be formed along the major surface of the substrate. For example, the storage element 202 may include a bottom electrode and a top electrode separated by a resistance switching layer. In some embodiments, the bottom and top electrodes may each include a via structure or a conductor line. The bottom electrode and the top electrode may comprise titanium, tantalum, titanium nitride, tantalum nitride, or one or more layers of other metal composite films. The resistance switching layer may include a transitional metal oxide comprising one or more layers of hafnium oxide, aluminum oxide, tantalum oxide, or other composite combinations such as hafnium aluminum oxide. In some other embodiments, the resistance switching layer can include one or more layers of carbon-based material, such as carbon nanotube material resistance switching layer.

In the example of the 1T1C configuration, the storage element 202 may be similarly formed between two adjacent ones of the metallization layers that are disposed vertically above the major surface of the substrate, while the access transistor 204 may be formed along the major surface of the substrate. For example, the storage element 202 may include a bottom electrode and a top electrode separated by a capacitor insulator layer. In some embodiments, the bottom and top electrodes may each include a via structure or a conductor line. The bottom electrode and the top electrode may comprise titanium, tantalum, titanium nitride, tantalum nitride, or one or more layers of other metal composite films. The capacitor insulator layer may include a dielectric material which may, for example, be or comprise, zirconium oxide, aluminum oxide, hafnium oxide, silicon oxide, some other suitable dielectric(s), or any combination of the foregoing. In some embodiments, the capacitor insulator layer is or comprises a metal oxide and/or is or comprises a high-k dielectric material. A high-k dielectric material may, for example, be a dielectric material having a dielectric constant greater than about 10 or some other suitable value. In some other embodiments, the capacitor insulator layer may include a ferroelectric insulating layer such as, for example, doped hafnium oxide, strontium bismuth tantalite, lead zirconate titanate, or a combination thereof. The doped hafnium oxide may, for example, be doped with zirconium, silicon, yttrium, aluminum, gadolinium, lanthanum, strontium, some other suitable element(s), or any combination of the foregoing.

In general, components formed along the major surface (e.g., the access transistor 204) are sometimes referred to as part of front-end-of-line (FEOL) processing/network, and the metallization layers and components formed in the metallization layers (e.g., the storage element 202) are sometimes referred to as part of back-end-of-line (BEOL) processing/network. The metallization layers may sometimes be referred to as M0 layer (optional), M1 layer, M2 layer, and so on, with the M0 layer (if formed) or the M1 layer being the bottommost metallization layer. Such BEOL components can include various conductor (e.g., metallic or metal) tracks disposed in each of the metallization layers, and various conductor (e.g., metallic or metal) via structures vertically interposed between the adjacent metallization layers. The conductor track, based on to which of the metallization layers it belongs, may be referred to as M0 track, M1 track, M2 track, etc., and the via structure, based on to which of the metallization layer it is connected, may be referred to as V0, V1, V2, etc. Further, there may be (e.g., conductor) components formed vertically between the FEOL network and the BEOL network, which are sometimes referred to as part of middle-end-of-line (MEOL) processing/network. Such MEOL components can include various conductor (e.g., metallic or metal) structures electrically connecting at least one FEOL component to a corresponding BEOL component. These MEOL components are sometimes referred to as MD, MP, VG, or VD. For example, the MD can electrically couple the source/drain terminal of a transistor to an upper BEOL component through the VD or V0; the MP can electrically couple the gate terminal of a transistor to a BEOL component through the V0; and the VG can electrically couple the gate terminal of a transistor to a BEOL component.

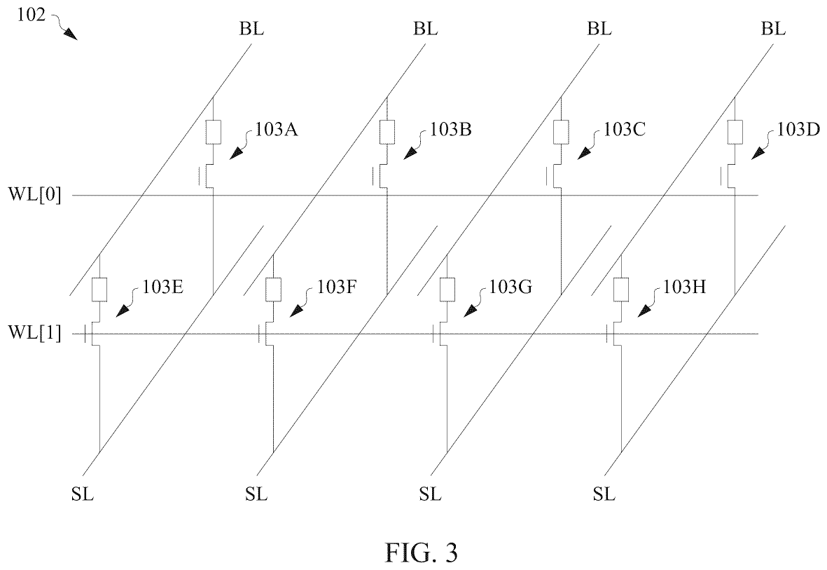

FIG. 3 illustrates an example schematic diagram of a portion of the memory array 102 (FIG. 1), in accordance with various embodiments. For example, the memory array 102 shown in FIG. 3 includes memory cells 103A, 103B, 103C, 103D, 103E, 103F, 103G, and 103H. The schematic diagram of FIG. 3 has been simplified for illustrative purposes, and thus, it should be understood that the partially shown memory array 102 of FIG. 3 can include any of various other components, while remaining within the scope of the present disclosure.

In some embodiments, the memory cells 103A to 103D may form a first subset of memory cells of the memory array 102 that are disposed along a first one of the rows, and the memory cells 103E to 103H may form a second subset of memory cells of the memory array 102 that are disposed along a second one of the rows. The first row can include or otherwise correspond to a first WL, WL[0] (e.g., an even-numbered WL indicated as WL[2N]), and the second row can include or otherwise correspond to a second WL, WL[1] (e.g., an odd-numbered WL indicated as WL[2N+1]), where N is an integer equal to or larger than 0. Further, the first subset of memory cells 103A to 103D may be disposed along a number of columns, respectively, and the second subset of memory cells 103E to 103H may be disposed along those same columns, respectively. Each of the columns can include or otherwise correspond to a respective BL and a respective SL.

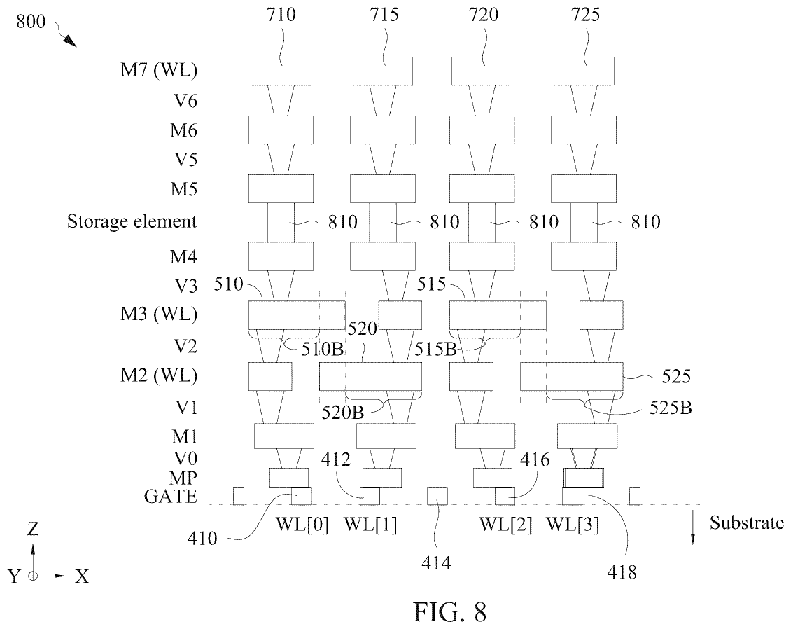

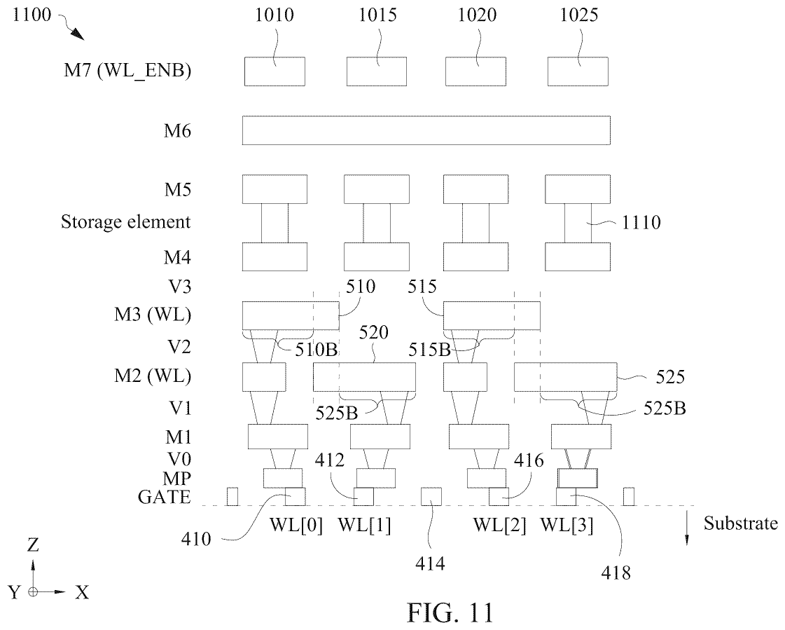

In various embodiments of the present disclosure, the first subset of memory cells 103A to 103H can have the respective source terminals of their access transistors coupled to one another through one or more MEOL components (e.g., MDs), which are further coupled to one or more SLs that are formed as first BEOL components (e.g., MI tracks). Similarly, the second subset of memory cells 103I to 103P can have the respective source terminals of their access transistors coupled to one another through one or more MEOL components (e.g., MDs), which are further coupled to the one or more SLs. Further, the first WL[0], connecting to the gate terminals of the first subset of memory cells 103A to 103D, can be formed as a second BEOL component (e.g., an M2 track) disposed one level above the M1 tracks (the SLs); and the second WL[1], connecting to the gate terminals of the second subset of memory cells 103E to 103H, can be formed as a third BEOL component (e.g., an M3 track) disposed one level above the M2 track (the first WL[0]). The storage elements of the memory cells 103A to 103P can be formed above the first and second WLs (e.g., between the M4 and M5 layers), with the BLs formed as one or more fourth BEOL components disposed further above the storage elements (e.g., M6 tracks). Details of arrangements of the memory cells 103A to 103P will be discussed further with respect FIGS. 8 and 11.

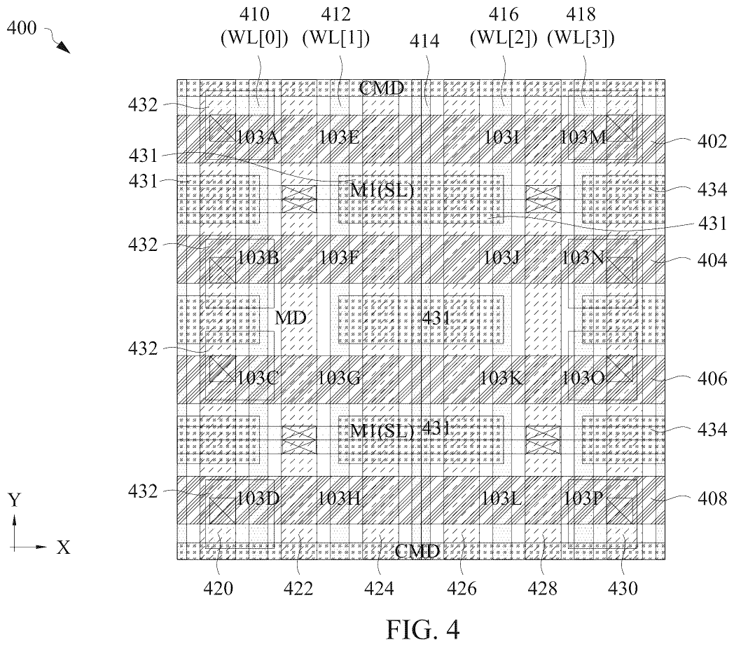

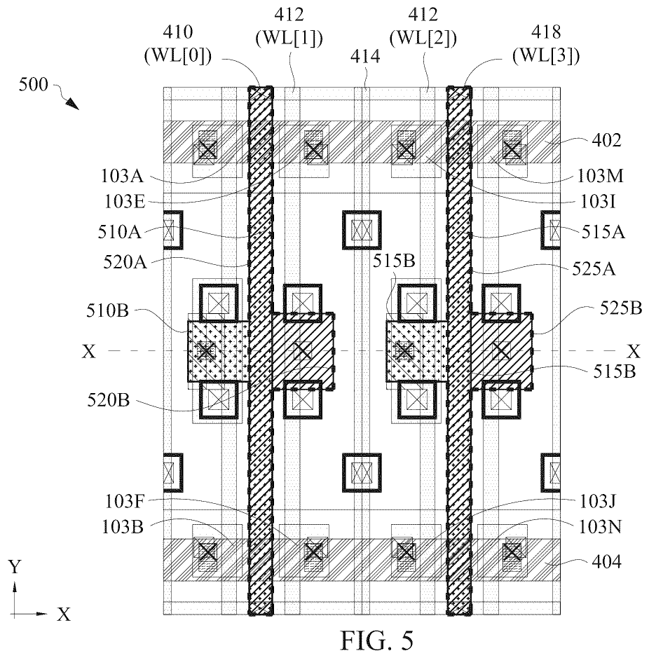

FIG. 4 illustrates a first layout 400 configured to form a number of the memory cells (e.g., 103A-103H), and FIG. 5 illustrates a second layout 500 configured to form a number of BEOL components operatively coupled to the memory cells (e.g., WL[0] and WL[1]), in accordance with various embodiments. The layouts 400 and 500 may be vertically overlapped with each other, and further, the layout 500 may correspond to (e.g., be disposed vertically above) a portion of the layout 400. The layouts 400 and 500 have been simplified for illustrative purposes, and thus, it should be understood that the layouts 400 and 500 can each have any of various other components while remaining within the scope of the present disclosure.

Referring first to FIG. 4, the layout 400 includes patterns 402, 404, 406, and 408 that are each configured to form an active region (hereinafter “active region 402,” “active region 404,” “active region 406,” and “active region 408,” respectively); and patterns 410, 412, 414, 416, and 418 that are each configured to form a gate structure (hereinafter “gate structure 410,” “gate structure 412,” “gate structure 414,” “gate structure 416,” and “gate structure 418,” respectively). In some embodiments, the active regions 402 to 408 may each extend along a first lateral direction (e.g., the X-direction), and the gate structures 410 to 418 may each extend along a second, different lateral direction (e.g., the Y-direction). The first lateral direction is perpendicular to the second lateral direction.

In some embodiments, each of the active regions 402 to 408 is formed of a fin-like structure or a stack structure protruding from the major (e.g., frontside) surface of a substrate. For example, the fin-like structure can continuously extend from the substrate. Portions of the fin-like structure that are overlaid by the gate structure remain, while other portions of the fin-like structure are replaced with a number of epitaxial structures. The remaining portions of the fin-like structures can be configured as the channel of a corresponding transistor, the epitaxial structures coupled to both sides (or ends) of the remaining portions of the fin-like structures can be configured as source/drain structures (or terminals) of the transistor, and a portion of the gate structure that overlays (e.g., straddles) the remaining portions of the fin-like structures can be configured as a gate structures (or terminal) of the transistor. For another example, the stack can include a number of semiconductor nanostructures (e.g., nanosheets) extending along the first lateral direction and vertically separated from each other. Portions of the semiconductor structures in the stack that are overlaid by the gate structure remain, while other portions are replaced with a number of epitaxial structures. The remaining portions of the semiconductor structures can be configured as the channel of a corresponding transistor, the epitaxial structures coupled to both sides (or ends) of the remaining portions of the semiconductor structures can be configured as source/drain structures (or terminals) of the transistor, and a portion of the gate structure that overlays (e.g., straddles) the remaining portions of the semiconductor structures can be configured as a gate structures (or terminal) of the transistor.

For example in FIG. 4, access transistors of the memory cells 103A tot 103D can be formed by the active regions 402 to 408 and the gate structure 410; and access transistors of the memory cells 103E to 103H can be formed by the active regions 402 to 408 and the gate structure 412. As such, the gate structure 410 can correspond to (e.g., be electrically coupled to) or otherwise serve as a part of the first WL (WL[0]), and the gate structure 412 can correspond to (e.g., be electrically coupled to) or otherwise serve as a part of the second WL (WL[1]). Additionally, the layout 400 can be utilized to form access transistors of memory cells 1031, 103J, 103K, and 103L, which can be formed by the active regions 402 to 408 and the gate structure 416, and access transistors of memory cells 103M, 103N, 1030, and 103P, which can be formed by the active regions 402 to 408 and the gate structure 418. In some embodiments, the gate structure 414 interposed between the gate structures 412 and 416 may be configured as a dummy gate structure (e.g., not functioning as a part of an active transistor).

The layout 400 further includes patterns 420, 422, 424, 426, 428, and 430 that are each configured to form a MEOL component, e.g., an MD (hereinafter “MD 420,” “MD 422,” “MD 424,” “MD 426,” “MD 428,” and “MD 430,” respectively). In some embodiments, each of the MDs 420, 424, 426, and 430 can be cut into a number of portions (sometimes referred to as cut MDs 420, cut MDs 424, cut MDs 426, cut MDs 430) through one or more cut-metal structures formed by patterns 431. These cut-metal structures (CMDs) can each traverse one or more of the MDs 420, 424, 426, and 430. On the other hand, the MDs 422 and 428 may remain uncut (sometimes referred to as uncut MDs 422 and 428), that is, continuously extending across multiple active structures along the Y-direction. Accordingly, the uncut MD can be electrically coupled to the source/drain terminals of a plural number of corresponding transistors, and the cut MD can be electrically coupled to the source/drain terminal of a single corresponding transistor.

In the example of FIG. 4, the uncut MD 422 is coupled to the source/drain terminals of the access transistors of the memory cells 103A to 103H (e.g., shorting the source terminals of the access transistors of the memory cells 103A to 103H); the uncut MD 428 is coupled to the source/drain terminals of the access transistors of the memory cells 1031 to 103P (e.g., shorting the source terminals of the access transistors of the memory cells 1031 to 103P); one of the cut MDs 420 is coupled to the source/drain terminal of the access transistor of the memory cell 103A; another one of the cut MDs 420 is coupled to the source/drain terminal of the access transistor of the memory cell 103B; and so on.

The layout 400 further includes a plural number of patterns 432 that are each configured to form a BEOL component in the M1 layer, e.g., an M1 island (hereinafter “M1 island 432”), and a plural number of patterns 434 that are each configured to form another BEOL component in the M1 layer, e.g., an MI track (hereinafter “M1 track 434”). In some embodiments, the M1 island 432 is configured to land on (e.g., electrically couple to) a corresponding one of the cut MDs, e.g., the cut MDs 420, the cut MDs 424, the cut MDs 426, the cut MDs 430, etc., through a corresponding via structure. As such, the M1 island 432 may not extend over more than one cut/uncut MD. The M1 track 434, which extends across multiple MDs along the X-direction, is configured to electrically couple to one or more uncut MDs, e.g., 422 and 428.

In various embodiments, the M1 tracks 434 may be configured as multiple SLs, respectively. As such, the access transistors of the memory cells 103A to 103P (formed based on the layout 400) can have one of their source/drain terminals shorted to each other through the M1 tracks 434 (SLs) and the underlying uncut MDs 422 and 428. For example in FIG. 4, the source terminals of the access transistors of the memory cells 103A to 103H can be coupled to one another through the uncut MD 422, and the source terminals of the access transistors of the memory cells 103I to 103P can be coupled to one another through the uncut MD 428. Further, these two uncut MDs 422 and 428 can be coupled to each other through the M1 tracks 434.

Referring next to FIG. 5, the layout 500, which may overlay a portion of the layout 400 (e.g., the portion including the patterns/structures to form the memory cells 103A-B, 103E-F, 103I-J, and 103M-N), includes patterns 510 and 515 that are each configured to form a BEOL component in the M3 layer, e.g., an M3 track (hereinafter “M3 track 510” and “M3 track 515,” respectively), and patterns 520 and 525 that are each configured to form a BEOL component in the M2 layer, e.g., an M2 track (hereinafter “M2 track 530” and “M2 track 535,” respectively). In some embodiments, the M3 tracks 510-515 and the M2 tracks 520-525 each extend along the Y-direction. Further, each of the M3 tracks 510-515 and the M2 tracks 520-525 includes a longitudinal portion extending in the Y-direction and a stitch portion protruding away from the longitudinal portion in the X-direction.

For example in FIG. 5, the M3 track 510 includes a longitudinal portion 510A and a stitch portion 510B; the M2 track 520 includes a longitudinal portion 520A and a stitch portion 520B; the M3 track 515 includes a longitudinal portion 515A and a stitch portion 515B; and the M2 track 525 includes a longitudinal portion 525A and a stitch portion 525B. The longitudinal portion 510A and the longitudinal portion 520A may be vertically overlapped with each other, while the stitch portion 510B and the stitch portion 520B may protrude toward opposite ways. Similarly, the longitudinal portion 515A and the longitudinal portion 525A may be vertically overlapped with each other, while the stitch portion 515B and the stitch portion 525B may protrude toward opposite ways.

In some embodiments, the M3 track 510 can operatively serve as the first WL, WL[0], which connects to the gate terminals of the access transistors of the memory cells 103A-B and 103C-D (not shown); and the M2 track 520 can operatively serve as the second WL, WL[1], which connects to the gate terminals of the access transistors of the memory cells 103E-F and 103G-H (not shown). Similarly, the M3 track 515 can operatively serve as a third WL, WL[2], which connects to the gate terminals of the access transistors of the memory cells 103I-J and 103K-L (not shown); and the M2 track 525 can operatively serve as a fourth WL, WL[3], which connects to the gate terminals of the access transistors of the memory cells 103M-N and 1030-P (not shown). According to the present disclosure, the WL[0] and WL[2] are referred to as even-numbered WLs, and the WL[1] and WL[3] are referred to as odd-numbered WLs.

With the adjacent even-numbered WL and odd-numbered WL (e.g., the WL[0] and WL[1]) formed in respective metallization layers, an arrangement of the WLs will not be limited by the relatively tight spacing (pitch) in the lower metallization layers and can be formed in these lower metallization layers (e.g., the M2 layer, M3 layer). Stated another way, the pitch of WLs in any of these metallization layers can be increased by two times. Advantageously, more room among these metallization layers can be spared for arranging other connections, and thus, a density of corresponding memory cells within a certain area can be significantly increased.

In some embodiments, the WL[0] (e.g., a portion of which is embodied as the M3 track 510) can be coupled to the gate terminals of the access transistors of the memory cells 103A-D through its stitch portion 510B, and the WL[1] (e.g., a portion of which is embodied as the M2 track 520) can be coupled to the gate terminals of the access transistors of the memory cells 103E-H through its stitch portion 520B. For example, the WL[0] (or the M3 track 510) can be coupled to the gate terminals of the corresponding memory cells 103A-D through the stitch portion 510B, one V2, one M2 track, one V1, one M1 track or island, one V0, and one MP, and the WL[1] (or the M2 track 520) can be coupled to the gate terminals of the corresponding memory cells 103E-H through the stitch portion 520B, another V1, another M1 track or island, another V0, and another MP, which can be better appreciated in the cross-sectional views of FIGS. 8 and 11.

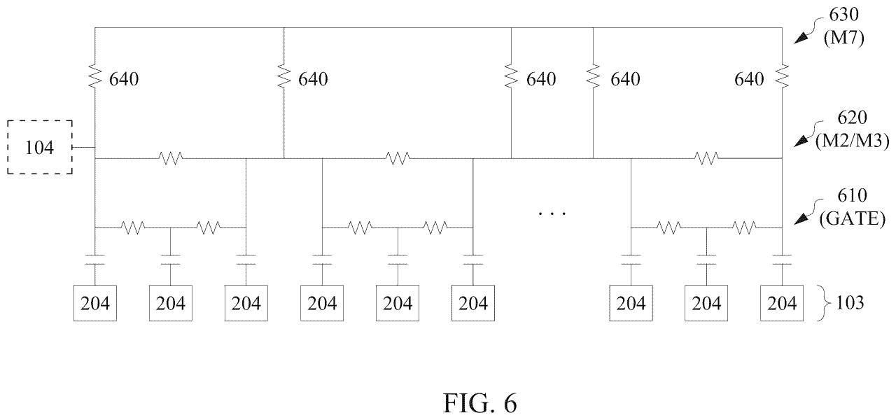

FIG. 6 illustrates an example schematic diagram of a portion of the memory array 102 (FIG. 1), in accordance with various embodiments. For example, the memory array 102 shown in FIG. 6 includes the gate terminals of access transistors 204 of a plural number of memory cells 103 that are coupled to one another through the same WL (e.g., along the same row). The gate terminals of these access transistors may be embodied as a single gate structure 610, which may be modeled as an RC circuit in FIG. 6. The schematic diagram of FIG. 6 has been simplified for illustrative purposes, and thus, it should be understood that the partially shown memory array 102 of FIG. 6 can include any of various other components, while remaining within the scope of the present disclosure.

In some embodiments, the schematic diagram of FIG. 6 is derived based on the schematic diagram of FIG. 3 and the layouts of FIGS. 4-5, and thus, the gate terminals of the respective access transistors of the memory cells 103 (implemented as the gate structure 610 in FIG. 6) are coupled to one another through one WL 620 that is formed as an M2 track or M3 track (hereinafter “M2/M3 track 620”), depending on whether the WL is odd-numbered or even-numbered. The M2/M3 track 620 may be further coupled to a metal track 630 disposed in a vertically higher metallization layer (e.g., the M7 layer). The additional metal track 630, e.g., implemented as an M7 track (hereinafter “M7 track 630”), is coupled to the M2/M3 track 620 in parallel through a number of storage elements 640 that are repurposed. These storage elements 640 may be interposed between the M4 layer and M5 layer, any of which is disposed vertically above the M2/M3 track 620, in some embodiments. The M7 track 630 generally has a larger dimension (e.g., a wider width) than the M2/M3 track 620, thus, a lower resistance. With such an arrangement, a total resistance of the WL (embodied as at least one M2/M3 track coupled in parallel with one M7 track) can be significantly decreased.

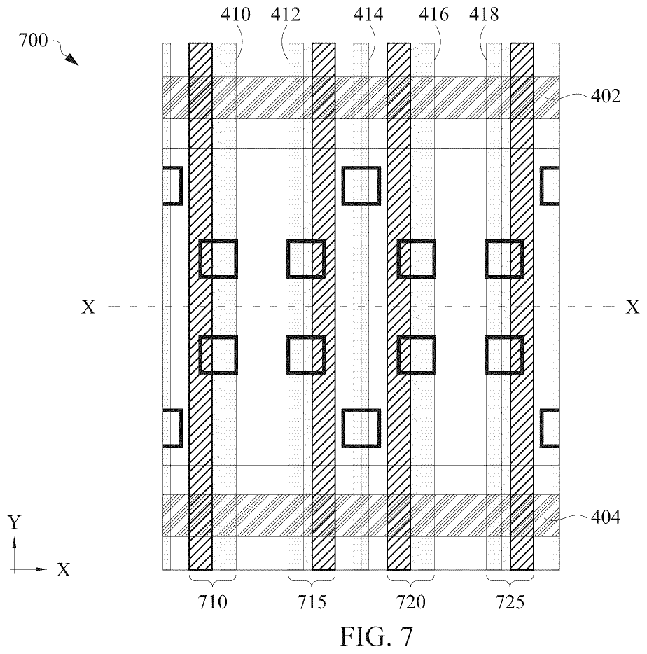

FIG. 7 illustrates an example layout 700 configured to form a plural number of these M7 tracks 630 that are each coupled to a corresponding one of the WLs formed as an M2/M3 track, in accordance with some embodiments. The layout 700 can be vertically overlapped with the (e.g., underlying) layout such as, the layout 400 (FIG. 4). Accordingly, some of the patterns of the layout 400 is shown in FIG. 7 as a reference. As shown, the layout 700 includes patterns 710, 715, 720, and 725 that are each configured to form an M7 track (hereinafter “M7 track 710,” “M7 track 715,” “M7 track 720” and “M7 track 725,” respectively). The M7 tracks 710 to 725 each extend along the Y-direction, and may laterally shifted away from or aligned with the corresponding (e.g., underlying) M2 and M3 tracks that are configured as the WLs.

FIG. 8 illustrates a cross-sectional view of a semiconductor structure 800 that may be formed collectively based on the layout 400 (FIG. 4), the layout 500 (FIG. 5), and the layout 700 (FIG. 7), in accordance with some embodiments. For example, the cross-sectional view of FIG. 8 may be cut along line X-X (indicated in FIGS. 5 and 7), which traverses the stitch portions of the M2 and M3 tracks that function as the WLs of a number of memory cells.

As shown, the gate structures 410, 412, 416, and 418, which operatively serve as portions of the WL[0], WL[1], WL[2], and WL[3], respectively, are formed along the major surface of a substrate. The WL[0] to WL[3] can each be operatively shared by a corresponding number of the memory cells 103 (e.g., 64 memory cells disposed along a certain row of a memory array). Over the gate structures 410 to 418, a plural number of metallization layers, e.g., from the M1 layer to the M7 layer, are formed.

In accordance with some embodiments of the present disclosure, one of the M2 tracks 520 that has the stitch portion 520B electrically coupled to the gate structure 412 (WL[1]) through a corresponding V1, a corresponding M1, a corresponding V0, and a corresponding MP; and another of the M2 tracks 525 that has the stitch portion 525B electrically coupled to the gate structure 418 (WL[3]) through a corresponding V1, a corresponding M1, a corresponding V0, and a corresponding MP. Similarly, one of the M3 tracks 510 that has the stitch portion 510B electrically coupled to the gate structure 410 (WL[0]) through a corresponding V2, a corresponding M2, a corresponding V1, a corresponding M1, a corresponding V0, and a corresponding MP; and another of the M3 tracks 515 that has the stitch portion 515B electrically coupled to the gate structure 416 (WL[2]) through a corresponding V2, a corresponding M2, a corresponding V1, a corresponding M1, a corresponding V0, and a corresponding MP. In some embodiments, the foregoing M1s, coupled to the respective gate structures, may not serve as any of the SLs. In some embodiments, the M2 track 520 and the M3 track 510 may have their respective longitudinal portions vertically aligned with each other (as indicted by the dotted lines in FIG. 8); and the M2 track 525 and the M3 track 515 may have their respective longitudinal portions vertically aligned with each other (as indicted by the dotted lines in FIG. 8).

Further, the M3 track 510 (a part of the WL[0]) may be coupled to the M7 track 710; the M2 track 520 (a part of the WL[1]) may be coupled to the M7 track 715; the M3 track 515 (a part of the WL[2]) may be coupled to the M7 track 720; and the M2 track 525 (a part of the WL[3]) may be coupled to the M7 track 725. The M7 tracks 710, 715, 720, and 725 may thus become parts of the WL[0], WL[1], WL[2], and WL[3], respectively. As shown, the M2 tracks 520-525 and the M3 tracks 510-515 may each be coupled to the corresponding M7 track using its stitch portion (e.g., with the stitch portion vertically aligned with the corresponding M7 track). However, other arrangement may also be contemplated.

In some embodiments of the present disclosure, the M2 tracks 520-525 and the M3 tracks 510-515 can each be coupled to the corresponding M7 track through a storage element 810 that is interposed between the M4 layer and M5 layer. The storage element 810, which may be formed as the MIM structure as described above, may be enlisted or repurposed as a via structure to electrically couple the M7 track to the underlying M2 or M3 track. It should be noted that respective storage elements of the memory cells 103 (driven by the WL[0] to WL[3]) may also be formed between the M4 layer and M5 layer, but laterally shifted from the enlisted storage elements 810. For example, the non-enlisted storage element, which still functions to store data, can be roughly aligned with the source/drain terminal of a corresponding access transistor that is formed along the major surface of the substrate.

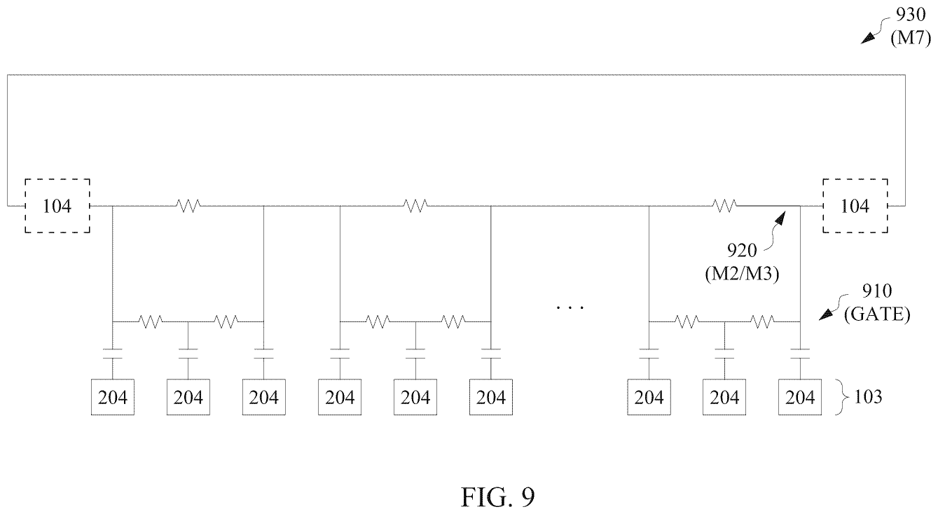

FIG. 9 illustrates an example schematic diagram of a portion of the memory array 102 (FIG. 1), in accordance with various embodiments. For example, the memory array 102 shown in FIG. 9 includes the gate terminals of access transistors 204 of a plural number of memory cells 103 that are coupled to one another through the same WL (e.g., along the same row). The gate terminals of these access transistors may be embodied as a single gate structure 910, which may be modeled as an RC circuit in FIG. 9. The schematic diagram of FIG. 9 has been simplified for illustrative purposes, and thus, it should be understood that the partially shown memory array 102 of FIG. 9 can include any of various other components, while remaining within the scope of the present disclosure.

In some embodiments, the schematic diagram of FIG. 9 is derived based on the schematic diagram of FIG. 3 and the layouts of FIGS. 4-5, and thus, the gate terminals of the respective access transistors of the memory cells 103 (implemented as the gate structure 910 in FIG. 9) are coupled to one another through one WL 920 that is formed as an M2 track or M3 track (hereinafter “M2/M3 track 920”), depending on whether the WL is odd-numbered or even-numbered. The M2/M3 track 920 may be operatively coupled to a WL driver (e.g., 104) through a metal track 930 disposed in a vertically higher metallization layer (e.g., the M7 layer). The additional metal track 930, e.g., implemented as an M7 track (hereinafter “M7 track 930”), may be configured to carry a WL enable signal to activate the M2/M3 track 920 (WL). For example, as long as the WL enable signal (WL_ENB) is pulled down, a WL signal carried on the M2/M3 track 920 can be pulled up, and vice versa. Thus, different from the schematic diagram of FIG. 6, the M7 track 930 may not be coupled to the M2/M3 track 620 through any storage element interposed between the M4 layer and M5 layer. Given the lower resistance of the M7 track 930 operatively coupled to both near and far ends of the M2/M3 track 920, a transition time period for the WL signal can be significantly reduced (e.g., by at least about 7%). With such an arrangement, a read/write speed of the memory cells can be significantly improved.

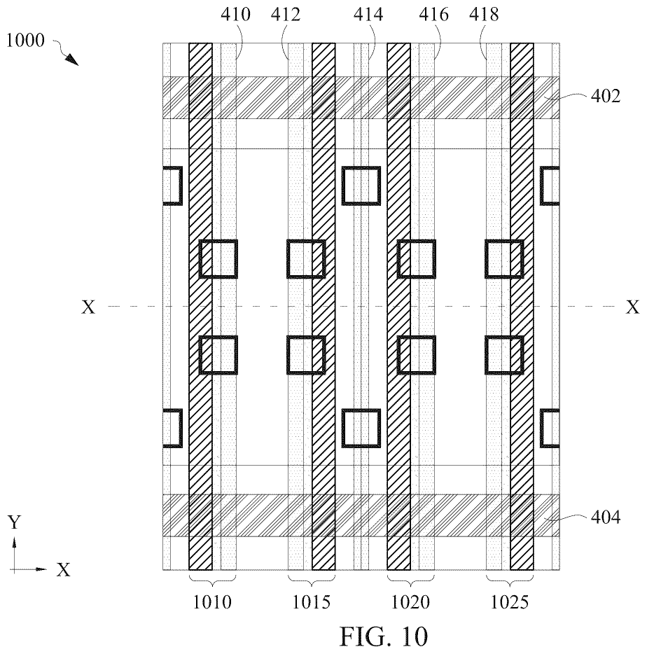

FIG. 10 illustrates an example layout 1000 configured to form a plural number of these M7 tracks 930 that are each coupled to the near end and the far end of a corresponding one of the WLs formed as an M2/M3 track through a near-end WL driver and a far-end WL driver, respectively, in accordance with some embodiments. The layout 1000 can be vertically overlapped with the (e.g., underlying) layout such as, the layout 400 (FIG. 4). Accordingly, some of the patterns of the layout 400 is shown in FIG. 10 as a reference. As shown, the layout 1000 includes patterns 1010, 1015, 1025, and 1025 that are each configured to form an M7 track (hereinafter “M7 track 1010,” “M7 track 1015,” “M7 track 1020” and “M7 track 1025,” respectively). The M7 tracks 1010 to 1025 each extend along the Y-direction, and may laterally shifted away from or aligned with the corresponding (e.g., underlying) M2 and M3 tracks that are configured as the WLs.

FIG. 11 illustrates a cross-sectional view of a semiconductor structure 1100 that may be formed collectively based on the layout 400 (FIG. 4), the layout 500 (FIG. 5), and the layout 1000 (FIG. 10), in accordance with some embodiments. For example, the cross-sectional view of FIG. 11 may be cut along line X-X (indicated in FIGS. 5 and 10), which traverses the stitch portions of the M2 and M3 tracks that function as the WLs of a number of memory cells.

As shown, the gate structures 410, 412, 416, and 418, which operatively serve as portions of the WL[0], WL[1], WL[2], and WL[3], respectively, are formed along the major surface of a substrate. The WL[0] to WL[3] can each be operatively shared by a corresponding number of the memory cells 103 (e.g., 64 memory cells disposed along a certain row of a memory array). Over the gate structures 410 to 418, a plural number of metallization layers, e.g., from the M1 layer to the M7 layer, are formed.

In accordance with some embodiments of the present disclosure, one of the M2 tracks 520 that has the stitch portion 520B electrically coupled to the gate structure 412 (WL[1]) through a corresponding V1, a corresponding M1, a corresponding V0, and a corresponding MP; and another of the M2 tracks 525 that has the stitch portion 525B electrically coupled to the gate structure 418 (WL[3]) through a corresponding V1, a corresponding M1, a corresponding V0, and a corresponding MP. Similarly, one of the M3 tracks 510 that has the stitch portion 510B electrically coupled to the gate structure 410 (WL[0]) through a corresponding V2, a corresponding M2, a corresponding V1, a corresponding M1, a corresponding V0, and a corresponding MP; and another of the M3 tracks 515 that has the stitch portion 515B electrically coupled to the gate structure 416 (WL[2]) through a corresponding V2, a corresponding M2, a corresponding V1, a corresponding M1, a corresponding V0, and a corresponding MP. In some embodiments, the foregoing M1s, coupled to the respective gate structures, may not serve as any of the SLs. In some embodiments, the M2 track 520 and the M3 track 510 may have their respective longitudinal portions vertically aligned with each other (as indicted by the dotted lines in FIG. 11); and the M2 track 525 and the M3 track 515 may have their respective longitudinal portions vertically aligned with each other (as indicted by the dotted lines in FIG. 11).

Further, the M3 track 510 (a part of the WL[0]) may be coupled to the M7 track 1010 through a corresponding WL driver formed along the major surface (not shown); the M2 track 520 (a part of the WL[1]) may be coupled to the M7 track 1015 through a corresponding WL driver formed along the major surface (not shown); the M3 track 515 (a part of the WL[2]) may be coupled to the M7 track 1020 through a corresponding WL driver formed along the major surface (not shown); and the M2 track 525 (a part of the WL[3]) may be coupled to the M7 track 1025 through a corresponding WL driver formed along the major surface (not shown). As shown, the M2 tracks 520-525 and the M3 tracks 510-515 may each have its stitch portion vertically aligned with the corresponding M7 track, but other arrangement may also be contemplated.

In some embodiments of the present disclosure, each of the M2 tracks 520-525 and the M3 tracks 510-515 may not be coupled to the corresponding M7 track through a storage element that is interposed between the M4 layer and M5 layer (e.g., 1110). Stated another way, the storage element 1110, which may be formed as the MIM structure as described above, may not be enlisted or repurposed as a via structure to electrically couple the M7 track to the underlying M2 or M3track. For example in FIG. 11, via strictures (e.g., V3's and V5's) may be absent above top electrodes of those storage elements 1110 and below bottom electrodes of those storage elements 1110, when compared to the semiconductor structure 800 shown in FIG. 8. Such storage elements 1110 can be disposed above the stitch portions 510B-525B, respectively. It should be noted that respective storage elements of the memory cells 103 (driven by the WL[0] to WL[3]) may also be formed between the M4 layer and M5 layer, but laterally shifted from the shown storage elements 1110.

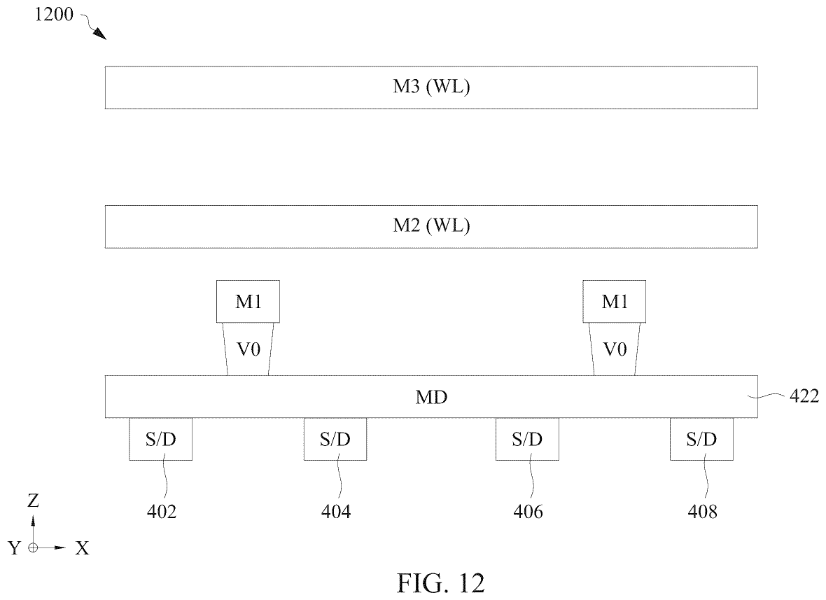

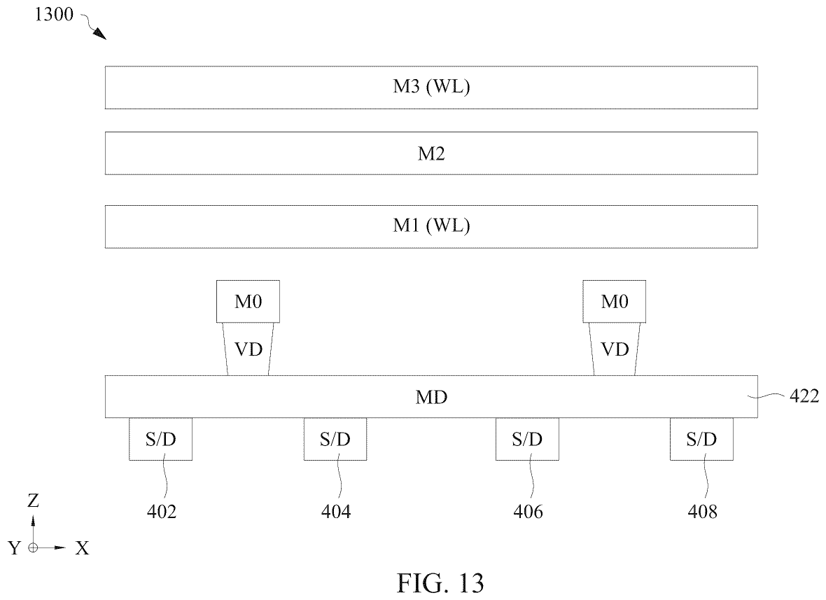

FIG. 12 and FIG. 13 illustrate cross-sectional views of semiconductor structures 1200 and 1300 that are formed collectively based on the layouts 400 and 500 (FIGS. 4-5), respectively, in accordance with various embodiments. For example, the cross-sectional views of FIGS. 12-13 may be cut along line Y-Y (indicated in FIG. 4), which extends along the M2 and M3 tracks that function as the WLs of a number of memory cells.

In FIG. 12, the semiconductor structure 1200 includes a number of source terminals (e.g., epitaxial structures) of the access transistors of the memory cells 103A to 103H, which are formed in the active regions 402, 404, 406, and 408, respectively. Over the source terminals, the MD 422 is formed to couple to those source/drain terminals. Above the MD 422, the semiconductor structure 1200 includes a number of M1 tracks coupled to the MD 422 through a number of V0's. In some embodiments, the M1 tracks, together with the MD, can operatively serve as the SL shorting the source terminals of the access transistors of the memory cells 103A to 103H. Further above the M1 tracks, the semiconductor structure 1200 includes at least one M2 track that operatively serves as a WL for the memory cells 103A-D, and at least one M3 track that operatively serves as a WL for the memory cells 103E-H. In some embodiments, the M1tracks, the M2 track, and the M3 track shown in the cross-sectional view of FIG. 12 may be formed based on the patterns 434, 520, and 510 of the layouts 400-500, respectively.

In FIG. 13, the semiconductor structure 1300 includes a number of source terminals (e.g., epitaxial structures) of the access transistors of the memory cells 103A to 103H, which are formed in the active regions 402, 404, 406, and 408, respectively. Over the source terminals, the MD 422 is formed to couple to those source/drain terminals. Above the MD 422, the semiconductor structure 1300 includes a number of M0 tracks coupled to the MD 422 through a number of VD's. In some embodiments, the M0 tracks, together with the MD, can operatively serve as the SL shorting the source terminals of the access transistors of the memory cells 103 A to 103H. Further above the M0 tracks, the semiconductor structure 1300 includes at least one M1 track that operatively serves as a WL for the memory cells 103A-D, and at least one M3 track that operatively serves as a WL for the memory cells 103E-H. In some embodiments, the M0 tracks, the M1 track, and the M3 track shown in the cross-sectional view of FIG. 13 may be formed based on the patterns 434, 520, and 510 of the layouts 400-500, respectively.

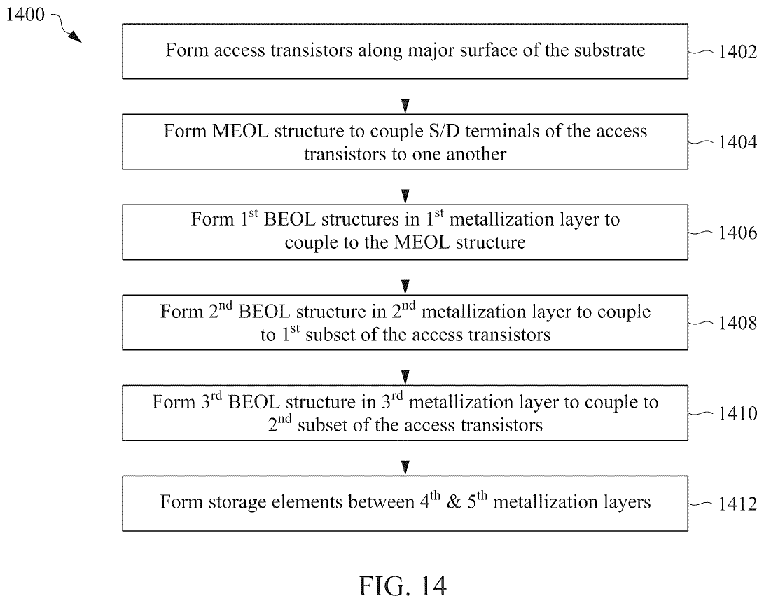

FIG. 14 illustrates a flowchart of an example method 1400 to form at least a portion of a memory array, according to one or more embodiments of the present disclosure. For example, the method 1400 can be performed to form a semiconductor (e.g., memory) device according to the layouts 400, 500, 700, and/or 1000. In some embodiments, the method 1400 includes operations to fabricate a number of memory cells, each of which includes an access transistor and a storage element. The access transistors have their source terminals coupled to one another through an M1 track or an M0 track (which operatively serves as one SL), and their gate terminals coupled to an M2 track and an M3 track or to an M1 track and an M3 track (which operatively serve as two WLs, respectively). The storage elements may be formed vertically above such WLs. It is noted that the method 1400 is merely an example and is not intended to limit the present disclosure. Accordingly, it is understood that additional operations may be provided before, during, and after the method 1400 of FIG. 14, and that some other operations may only be briefly described herein.

The method 1400 starts with operation 1402 in which a number of access transistors are formed along the major surface of a substrate, in accordance with various embodiments. Such access transistors can be formed according to the patterns 402-408 and 410-412 of FIG. 4, which forms a portion of a memory array, e.g., the access transistors of eight memory cells (103A to 103H) that are arranged across two rows and four columns.

The substrate includes a semiconductor material substrate, for example, silicon. Alternatively, the substrate may include other elementary semiconductor material such as, for example, germanium. The substrate may also include a compound semiconductor such as silicon carbide, gallium arsenic, indium arsenide, and indium phosphide. The substrate may include an alloy semiconductor such as silicon germanium, silicon germanium carbide, gallium arsenic phosphide, and gallium indium phosphide. In one embodiment, the substrate includes an epitaxial layer. For example, the substrate may have an epitaxial layer overlying a bulk semiconductor. Furthermore, the substrate may include a semiconductor-on-insulator (SOI) structure. For example, the substrate may include a buried oxide (BOX) layer formed by a process such as separation by implanted oxygen (SIMOX) or other suitable technique, such as wafer bonding and grinding.

The access transistors can each be formed as any of a planar transistor, a fin-like transistor, a gate-all-around (GAA) transistor, or the like. In the example of GAA transistors, a number of stacks can be defined on the substrate according to the patterns 402-408. Each of the stacks includes an alternating series of first nanostructures and second nanostructures. The first nanostructures may include SiGe sacrificial nanostructures, and the second nanostructures may include Si channel nanostructures. Such a stack may sometimes be referred to as a superlattice. In a non-limiting example, the SiGe sacrificial nanostructures can be SiGe 25%. The notation “SiGe 25%” is used to indicate that 25% of the SiGe material is Ge. It is understood the percentage of Ge in each of the SiGe sacrificial nanostructures can be any value between 0 and 100 (excluding 0 and 100), while remaining within the scope of present disclosure. In some other embodiments, the second nanostructures may include a first semiconductor material other than Si and the first nanostructures may include a second semiconductor material other than SiGe, as long as the first and second semiconductor materials are respectively characterized with different etching properties (e.g., etching rates).

After forming the stacks, a number of dummy gate structures can be formed according to the patterns 410-412. The dummy gate structures are formed by depositing amorphous silicon (a-Si) over the stacks. Other materials suitable for forming dummy gates (e.g., polysilicon) can be used while remaining within the scope of present disclosure. The a-Si is then planarized to a desired level. A hard mask is deposited over the planarized a-Si and patterned. The hard mask can be formed from a nitride or an oxide layer. An etching process (e.g., a reactive-ion etching (RIE) process) is applied to the a-Si to form the dummy gate structures.

After forming the dummy gate structures, gate spacers may be formed to extend along sidewalls of each of the dummy gate structures. The gate spacers can be formed by a conformal deposition of a dielectric material (e.g., silicon oxide, silicon nitride, silicon oxynitride, SiBCN, SiOCN, SiOC, or any suitable combination of those materials) followed by a directional etch (e.g., RIE). Next, inner spacers can be formed by replacing end portions of each of the SiGe sacrificial nanostructures with a dielectric material. Next, a number of epitaxial structures are formed using an epitaxial layer growth process on exposed ends of the Si nanostructures. In-situ doping (ISD) may be applied to form doped epitaxial structures, which operatively serve as source/drain terminals of the access transistors. Next, the dummy gate structures and the remaining SiGe sacrificial nanostructures are replaced with respective active gate structures. As such, the active gate structures 410 and 412 can each wrap around each of the Si nanostructures that are formed based on the active regions 402 to 408. In some embodiments, the active gate structure 410 may operatively serve as a part of a WL for a first subset of the memory cells 103A-D, and the active gate structure 412 may operatively serve as a part of a WL for a second subset of the memory cells 103E-H.

The method 1400 continues to operation 1404 in which a MEOL structure is formed to couple source terminals or drain terminals of the access transistors to one another, in accordance with various embodiments. For example, the MEOL structure may be the MD 422 extending between the active gate structures 410 and 412.

The MD 422 may be formed of a metal material. The metal material can be selected from the group consisting of aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The frontside interconnect structures can be formed by overlaying the frontside of the substrate with the above-listed metal material by, for example, chemical vapor deposition (CVD), physical vapor deposition (PVD), electroless plating, electroplating, or combinations thereof.

The method 1400 continues to operation 1406 in which a number of first BEOL structures disposed in a first metallization layer are formed to couple to the MEOL structure, in accordance with various embodiments. For example, the first BEOL structures may be the M1tracks 434. The M1 tracks 434 can traverse a plural number of MEOL structures similar to the MD 422. In some embodiments, the M1 tracks 434 and the electrically coupled MD 422 may operatively serve as a SL of the memory cells 103A-H.

The M1 tracks 434 may be formed of a metal material. The metal material can be selected from the group consisting of aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The frontside interconnect structures can be formed by overlaying the frontside of the substrate with the above-listed metal material by, for example, chemical vapor deposition (CVD), physical vapor deposition (PVD), electroless plating, electroplating, or combinations thereof.

The method 1400 continues to operation 1408 in which a second BEOL structure disposed in a second metallization layer is formed to couple to the gate terminals of a first subset of the access transistors, in accordance with various embodiments. For example, the second BEOL structure may be the M2 track 520 that includes a longitudinal portion and a stitch portion. In some embodiments, the M2 track 520 can operatively serve as another part of the WL for the second subset of the memory cells 103E-H. For example, the stitch portion of the M2 track 520 can be utilized to electrically connect to the active gate structure 412.

The M2 track 520 may be formed of a metal material. The metal material can be selected from the group consisting of aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The frontside interconnect structures can be formed by overlaying the frontside of the substrate with the above-listed metal material by, for example, chemical vapor deposition (CVD), physical vapor deposition (PVD), electroless plating, electroplating, or combinations thereof.

The method 1400 continues to operation 1410 in which a third BEOL structure disposed in a third metallization layer is formed to couple to the gate terminals of a second subset of the access transistors, in accordance with various embodiments. For example, the third BEOL structure may be the M3 track 510 that also includes a longitudinal portion and a stitch portion. However, the stitch portion of the M2 track 520 and the stitch portion of the M3 track 510 may point toward opposite ways. In some embodiments, the M3 track 510 can operatively serve as another part of the WL for the first subset of the memory cells 103A-D. For example, the stitch portion of the M3 track 510 can be utilized to electrically connect to the active gate structure 410.

The M3 track 510 may be formed of a metal material. The metal material can be selected from the group consisting of aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The frontside interconnect structures can be formed by overlaying the frontside of the substrate with the above-listed metal material by, for example, chemical vapor deposition (CVD), physical vapor deposition (PVD), electroless plating, electroplating, or combinations thereof.

The method 1400 continues to operation 1412 in which a number of storage elements are formed between a fourth metallization layer and a fifth metallization layer that are disposed vertically above the second BEOL structure and third BEOL structure, in accordance with various embodiments. For example, the storage elements may be formed between the M4 layer and the M5 layer. In some embodiments, the storage elements can be formed based on an MIM configuration, e.g., having an insulator layer vertically interposed between a bottom electrode and a top electrode. The storage elements are electrically coupled to the access transistors formed along the major surface of the substrate in series, thereby forming the memory cells 103A-H. For example, each of the storage elements may be vertically aligned with at least one component (e.g., a source or drain terminal) of the corresponding one of the access transistors.

In one aspect of the present disclosure, a memory device is disclosed. The memory device includes a plurality of first memory cells, each of the plurality of first memory cells including a respective first transistor and a respective first storage element, the first transistor formed along a major surface of a substrate and arranged along a first lateral direction, the first storage element formed in a first one of a plurality of metallization layers vertically disposed over the major surface. The memory device includes a plurality of second memory cells, each of the plurality of second memory cells including a respective second transistor and a respective second storage element, the second transistor formed along the major surface of the substrate and arranged along the first lateral direction, the second storage element formed in a second one of the plurality of metallization layers, wherein the second transistors of the second memory cells are arranged with respect to the first transistors of the first memory cells along a second lateral direction perpendicular to the first lateral direction. The memory device includes a first metal track extending along the first lateral direction, disposed in a third one of the plurality of metallization layers, and including a first stitch portion extending away from the first metal track in the second lateral direction, wherein the first stitch portion is configured to couple to respective gate structures of the first transistors of the first memory cells. The memory device includes a second metal track extending along the first lateral direction, disposed in a fourth one of the plurality of metallization layers, and including a second stitch portion extending away from the second metal track in the second lateral direction, wherein the second stitch portion is configured to couple to respective gate structures of the second transistors of the second memory cells.

In another aspect of the present disclosure, a memory device is disclosed. The memory device includes a memory array comprising a plurality of memory cells arranged over a plurality of rows, the rows including a plurality of word lines, respectively, a first group of the memory cells coupled to an even-numbered one of the word lines and a second group of the memory cells coupled to an odd-numbered one of the word lines. The even-numbered word line is disposed in a first one of a plurality of metallization layers formed vertically above a substrate, wherein the even-numbered word line extends along a first lateral direction and includes a first stitch portion extending in a second lateral direction perpendicular to the first lateral direction. The odd-numbered word line is disposed in a second one of the plurality of metallization layers, wherein the odd-numbered word line extends along the first lateral direction and includes a second stitch portion extending in the second lateral direction.

In yet another aspect of the present disclosure, a method for forming memory devices is disclosed. The method includes forming a first group of transistors and a second group of transistors along a major surface of a substrate, wherein the first group of transistors are aligned along a first lateral direction and the second group of transistors are aligned along the first lateral direction, and the first group of transistors and the second group of transistors are arranged with respect to each other along a second lateral direction perpendicular to the first lateral direction. The method includes forming a first metal track in a first one of a plurality of metallization layers disposed vertically above the major surface, wherein the first metal track extends along the first lateral direction, and includes a first stitch portion extending in the second lateral direction and coupled to gate structures of the first group of transistors, respectively. The method includes forming a second metal track in a second one of the plurality of metallization layers, wherein the second metal track extends along the first lateral direction, and includes a second stitch portion extending in the second lateral direction and coupled to gate structures of the second group of transistors, respectively. The method includes forming a first group of storage elements in a third one of the plurality of metallization layers, wherein the first group of storage elements are coupled to the first group transistors, respectively. The method includes forming a second group of storage elements in the third metallization layer, wherein the second group of storage elements are coupled to the second group transistors, respectively.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of first memory cells, each of the plurality of first memory cells including a respective first transistor and a respective first storage element, the first transistor formed along a major surface of a substrate and arranged along a first lateral direction;
a plurality of second memory cells, each of the plurality of second memory cells including a respective second transistor and a respective second storage element, the second transistor formed along the major surface of the substrate and arranged along the first lateral direction;
a first metal track operatively configured as a first word line of the plurality of first memory cells and extending along the first lateral direction, disposed in a first one of a plurality of metallization layers vertically disposed over the major surface, and including a first stitch portion extending away from the first metal track in a second lateral direction perpendicular to the first lateral direction; and
a second metal track operatively configured as a second word line of the plurality of second memory cells and extending along the first lateral direction, disposed in a second one of the plurality of metallization layers vertically separated from the first metallization layer, and including a second stitch portion extending away from the second metal track in the second lateral direction.

2. The memory device of claim 1, wherein the first storage element of each of the first memory cells and the second element of each of the second memory cells are formed in a third one of the plurality of metallization layers.

3. The memory device of claim 2, wherein the first and second metallization layers are each vertically disposed lower than the third metallization layer.

4. The memory device of claim 1, wherein the first metal track and the second metal track are vertically aligned with each other.

5. The memory device of claim 1, wherein the first stitch portion and the second stitch portion extend away from each other.

6. The memory device of claim 1, wherein the first stich portion is configured to couple to respective gate structures of the first transistors of the first memory cells, and the second stich portion is configured to couple to respective gate structures of the second transistors of the second memory cells.

7. The memory device of claim 1, wherein the second transistors of the second memory cells are arranged with respect to the first transistors of the first memory cells along the second lateral direction.

8. The memory device of claim 1, further comprising:
a plurality of third memory cells, each of the plurality of third memory cells including a respective third transistor and a respective third storage element, the third transistor formed along the major surface of the substrate and arranged along the first lateral direction;
a plurality of fourth memory cells, each of the plurality of fourth memory cells including a respective fourth transistor and a respective fourth storage element, the fourth transistor formed along the major surface of the substrate and arranged along the first lateral direction;
a third metal track operatively configured as a third word line of the plurality of third memory cells and extending along the first lateral direction, disposed in the first metallization layer, and including a third stitch portion extending away from the third metal track in the second lateral direction; and
a fourth metal track operatively configured as a fourth word line of the plurality of fourth memory cells and extending along the first lateral direction, disposed in the second metallization layer, and including a fourth stitch portion extending away from the fourth metal track in the second lateral direction.

9. The memory device of claim 8, wherein the first word line and the third word line are each configured as an even-numbered word line, and the second word line and the fourth word line are each configured as an odd-numbered word line.

10. The memory device of claim 8, wherein the third metal track and the fourth metal track are vertically aligned with each other.

11. The memory device of claim 8, wherein the third stitch portion and the fourth stitch portion extend away from each other.

12. The memory device of claim 1, wherein the first storage elements of the first memory cells and the second storage elements of the second memory cells each include a resistor or a capacitor.

13. A memory device, comprising:
a plurality of first memory cells, each of the plurality of first memory cells including a respective first transistor and a respective first storage element, the first transistor formed along a major surface of a substrate and arranged along a first lateral direction;
a plurality of second memory cells, each of the plurality of second memory cells including a respective second transistor and a respective second storage element, the second transistor formed along the major surface of the substrate and arranged along the first lateral direction;
a first metal track operatively configured as a first word line of the plurality of first memory cells and extending along the first lateral direction, disposed in a first one of a plurality of metallization layers vertically disposed over the major surface, and including a first stitch portion extending away from the first metal track in a second lateral direction perpendicular to the first lateral direction; and
a second metal track operatively configured as a second word line of the plurality of second memory cells and extending along the first lateral direction, disposed in a second one of the plurality of metallization layers vertically separated from the first metallization layer, and including a second stitch portion extending away from the second metal track in the second lateral direction;
wherein the first metal track and the second metal track are vertically overlapped with each other, and the first stitch portion and the second stitch portion extend away from each other.

14. The memory device of claim 13, wherein the first word line is configured as an even-numbered word line, and the second word line is configured as an odd-numbered word line.

15. The memory device of claim 13, wherein the first storage element of each of the first memory cells and the second element of each of the second memory cells are formed in a third one of the plurality of metallization layers, and the first and second metallization layers are each vertically disposed lower than the third metallization layer.

16. The memory device of claim 13, wherein the first stich portion is configured to couple to respective gate structures of the first transistors of the first memory cells, and the second stich portion is configured to couple to respective gate structures of the second transistors of the second memory cells.

17. The memory device of claim 13, wherein the second transistors of the second memory cells are arranged with respect to the first transistors of the first memory cells along the second lateral direction.

18. A memory device, comprising:
a plurality of first memory cells, each of the plurality of first memory cells including a respective first transistor and a respective first storage element, the first transistor formed along a major surface of a substrate;
a plurality of second memory cells, each of the plurality of second memory cells including a respective second transistor and a respective second storage element, the second transistor formed along the major surface of the substrate;
a first metal track operatively configured as a first word line of the plurality of first memory cells and extending along a first lateral direction, disposed in a first one of a plurality of metallization layers vertically disposed over the major surface, and including a first stitch portion extending away from the first metal track in a second lateral direction perpendicular to the first lateral direction; and
a second metal track operatively configured as a second word line of the plurality of second memory cells and extending along the first lateral direction, disposed in a second one of the plurality of metallization layers vertically separated from the first metallization layer, and including a second stitch portion extending away from the second metal track in the second lateral direction;
wherein the first metal track and the second metal track are vertically overlapped with each other, and the first stitch portion and the second stitch portion extend away from each other.

19. The memory device of claim 18, wherein the first transistors are arranged along the first lateral direction, the second transistors are arranged along the first lateral direction, and the second transistors are arranged with respect to the first transistors along the second lateral direction.

20. The memory device of claim 18, wherein the first word line is configured as an even-numbered word line, and the second word line is configured as an odd-numbered word line.
